(19) United States
(12) Patent Application Publication
(10) Pub. No.: US 2012/0326301 A1
(43) Pub. Date: Dec. 27, 2012

(54) THERMOSETTING RESIN COMPOSITION, FLIP-CHIP MOUNTING ADHESIVE, SEMICONDUCTOR DEVICE FABRICATION METHOD, AND SEMICONDUCTOR DEVICE

(75) Inventors: Sayaka Wakioka, Osaka (JP); Yangsoo Lee, Osaka (JP); Atsushi Nakayama, Osaka (JP); Carl Alvin Dilao, Osaka (JP)

(73) Assignee: Sekisui Chemical Co., Ltd., Osaka-shi, Osaka (JP)

(21) Appl. No.: 13/574,149

(22) PCT Filed: Jan. 19, 2011
(86) PCT No.: PCT/JP2011/050802

§ 371 Date: Sep. 12, 2012

(30) Foreign Application Priority Data
Jan. 21, 2010 (JP) 2010-011307

(51) Int. Cl. C09J 163/00; H01L 23/498; C09J 163/02; H01L 21/50

(52) U.S. Cl. 257/737; 438/108; 525/404; 525/529; 257/E21.499; 257/E23.068

(57) ABSTRACT

The present invention is aimed to provide a thermosetting resin composition which is easily produced, has excellent storage stability and thermal stability while maintaining high transparency and preventing formation of voids on the occasion of semiconductor chip bonding, and gives a cured product having excellent heat resistance, a flip-chip mounting adhesive containing the thermosetting resin composition, a method for producing a semiconductor device using the flip-chip mounting adhesive, and a semiconductor device produced by the method for producing a semiconductor device. The present invention is a thermosetting resin composition including an epoxy resin, an acid anhydride having a bicycle skeleton, and an imidazole curing accelerator that is in a liquid form at an ordinary temperature.

### TECHNICAL FIELD

The present invention relates to a thermosetting resin composition which is easily produced, has excellent storage stability and thermal stability while maintaining high transparency and preventing formation of voids on the occasion of semiconductor chip bonding, and gives a cured product having excellent heat resistance. The present invention also relates to a flip-chip mounting adhesive containing the thermosetting resin composition, a method for producing a semiconductor device using the flip-chip mounting adhesive, and a semiconductor device produced by the method for producing a semiconductor device.

### BACKGROUND ART

Epoxy resin compositions are widely used in various fields because of the advantageous features of cured products thereof, such as excellent adhesiveness, heat resistance, chemical resistance, and electric property. For example, in production of semiconductor devices, a bonding process is performed to attach and fix semiconductor chips to a substrate or another semiconductor chip. In the bonding process, epoxy resin adhesives, epoxy resin adhesive sheets, or the like which contain an acid anhydride as a curing agent are nowadays often used.

Epoxy resin compositions containing an acid anhydride are useful as adhesives for bonding because they have low viscosity and excellent storage stability, and the cured products thereof are excellent in mechanical strength, heat resistance, electric property, or the like. However, curing reaction of epoxy resin compositions containing an acid anhydride proceeds slowly, and needs heating at high temperature for a long time. For this reason, generally an acid anhydride is often used in combination with a curing accelerator.

For example, a curing accelerator used in combination with an acid anhydride is exemplified by imidazole curing accelerators. Addition of the imidazole curing accelerators can achieve epoxy resin compositions which are excellent in storage stability and are thermoset at relatively low temperature in a short time. As an example of the epoxy resin compositions containing an acid anhydride and an imidazole curing accelerator, Patent Literature 1 discloses an epoxy resin composition that contains an epoxy resin and a curing agent, and is in a liquid form at an ordinary temperature. The curing agent includes a specific acid anhydride and at least either of amine adduct particles and fine spherical particles obtained by coating a core formed of a compound having an imidazole skeleton with a coat formed of a thermosetting resin.

Meanwhile, semiconductor devices are further reduced in size and further integrated recently, leading to production of, for example, flip chips having a plurality of protrusions (bumps) as electrodes on the surface, stacked chips in which a plurality of thinly ground semiconductor chips are stacked, or the like. Moreover, the production process is further automated for efficient production of such compact and highly-integrated semiconductor devices.

In the recent automated bonding process, especially a flip-chip bonding process, a camera automatically recognizes a pattern or position indication on a semiconductor chip to perform alignment of the semiconductor chip. On this occasion, the pattern or position indication is recognized through an adhesive applied on the semiconductor chip. Therefore, the adhesive used for bonding is required to have a transparency to the extent that the camera can automatically recognize the pattern or position indication sufficiently.

However, despite a demand for a high transparency, most imidazole curing accelerators are in a solid form at an ordinary temperature and are included in a finely pulverized state, causing a reduction in the transparency of the epoxy resin composition. Moreover, necessity of pulverization and mixing of the imidazole curing accelerator and easy clogging of filters during filtration of the epoxy resin composition problematically lead to deterioration of workability.

### CITATION LIST

### Patent Literature

[Patent Literature 1] Japanese Kokai Publication No. 2006-328246 (JP-A 2006-328246)

### SUMMARY OF INVENTION

### Technical Problem

The present invention is aimed to provide a thermosetting resin composition which is easily produced, has excellent storage stability and thermal stability while maintaining high transparency and preventing formation of voids on the occasion of semiconductor chip bonding, and gives a cured product having excellent heat resistance. The present invention is also aimed to provide a flip-chip mounting adhesive containing the thermosetting resin composition, a method for producing a semiconductor device using the flip-chip mounting adhesive, and a semiconductor device produced by the method for producing a semiconductor device.

### Solution to Problem

The present invention is a thermosetting resin composition including an epoxy resin, an acid anhydride having a bicyclo skeleton, and an imidazole curing accelerator that is in a liquid form at an ordinary temperature. The following describes the present invention in more detail.

In order to enhance the transparency of a thermosetting resin composition obtained by mixing an acid anhydride with an imidazole curing accelerator, the inventors of the present application conceived of a use of an imidazole curing accelerator that is in a liquid form at an ordinary temperature instead of an imidazole curing accelerator that is in a solid format an ordinary temperature. Furthermore, the inventors conceived of the following: use of an imidazole curing accelerator that is in a liquid form at an ordinary temperature can avoid necessity of pulverization of the imidazole curing accelerator, which leads to easy production of a highly transparent thermosetting resin composition. Moreover, since the imidazole curing accelerator that is in a liquid form at an ordinary temperature can be uniformly dispersed at the molecular level, local heat generation can be prevented on the occasion of semiconductor chip bonding, thereby preventing formation of voids.

However, the inventors found that mixing of the imidazole curing accelerator that is in a liquid form at an ordinary temperature deteriorates the storage stability and thermal stability of thermosetting resin compositions, and thus it is difficult to achieve all of the stability, transparency, productivity, and performances such as suppression of void. In particular, it is difficult to use thermosetting resin compositions having low stability as flip-chip bonding adhesives which need to be stable at an ordinary temperature or high temperature for a long time.

The inventors of the present application have found that combination use of an acid anhydride having a bicyclo skeleton and an imidazole curing accelerator that is in a liquid form at an ordinary temperature can suppress deterioration of the storage stability and the thermal stability while maintaining the transparency of the thermosetting resin composition and preventing formation of voids on the occasion of semiconductor chip bonding. Furthermore, the inventors have found that the cured products of such a thermosetting resin composition, has excellent heat resistance.

Namely, the inventors have found that a thermosetting resin composition containing an epoxy resin, an acid anhydride having a bicyclo skeleton, and an imidazole curing accelerator that is in a liquid form at an ordinary temperature is easily produced, has excellent storage stability and thermal stability while maintaining high transparency and preventing formation of voids on the occasion of semiconductor chip bonding, and gives a cured product having excellent heat resistance. Accordingly, they completed the present invention.

The thermosetting resin composition of the present invention contains an epoxy resin.

The epoxy resin is not particularly limited, and is preferably an epoxy resin having a polycyclic hydrocarbon skeleton in the main chain. A thermosetting resin composition containing the epoxy resin having a polycyclic hydrocarbon skeleton in the main chain gives a cured product that is rigid enough to disturb molecular motion therein, and thus is excellent in mechanical strength and heat resistance. Moreover, the cured product is also excellent in damp proofness because of its low water absorbability.

The epoxy resin having a polycyclic hydrocarbon skeleton in the main chain is not particularly limited, and examples thereof include: epoxy resins having a dicyclopentadiene skeleton (hereinafter, also referred to as dicyclopentadiene-type epoxy resins) such as dicyclopentadiene dioxide and a phenol novolac epoxy resin having a dicyclopentadiene skeleton; epoxy resins having a naphthalene skeleton (hereinafter, also referred to as naphthalene-type epoxy resins) such as 1-glycidyl naphthalene, 2-glycidyl naphthalene, 1,2-diglycidyl naphthalene, 1,5-diglycidyl naphthalene, 1,6-diglycidyl naphthalene, 1,7-diglycidyl naphthalene, 2,7-diglycidyl naphthalene, triglycidyl naphthalene, and 1,2,5,6-tetraglycidyl naphthalene; tetrahydroxy phenylethane-type epoxy resins, tetrakis(glycidyloxyphenyl)ethane, and 3,4-epoxy-6-methylcyclohexylmethyl-3,4-epoxy-6-methylcyclohexane carbonate. Among these, dicyclopentadiene-type epoxy resins and naphthalene-type epoxy resins are preferable.

Each of these epoxy resins having a polycyclic hydrocarbon skeleton in the main chain may be used alone, or two or more of these may be used in combination. Moreover, multipurpose epoxy resins such as bisphenol A-type epoxy resins and bisphenol F-type epoxy resins may be used in combination.

The naphthalene-type epoxy resin preferably contains a compound having a structure represented by the following Formula (1). Inclusion of the compound represented by Formula (1) reduces the linear expansion coefficient of a cured product of an obtainable thermosetting resin composition to increase the heat resistance and adhesion property of the cured product. As a result, higher bonding reliability is achieved.

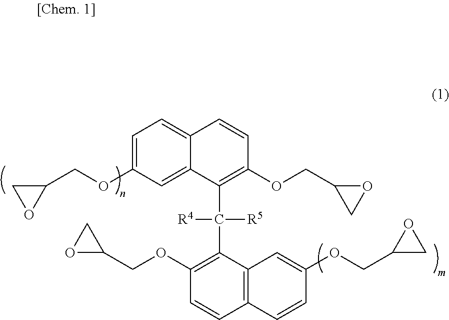

In Formula (1), R⁴ and R⁵ each represent a hydrogen atom, a halogen atom, an alkyl group, an aryl group, or a phenyl group, and n and m each represent 0 or 1.

In the case where the epoxy resin contains a compound represented by Formula (1), the amount of the compound in the epoxy resin is not particularly limited. The preferable lower limit thereof is 3% by weight and the preferable upper limit thereof is 90% by weight. If the amount of the compound represented by Formula (1) is less than 3% by weight, the linear expansion coefficient of a cured product of an obtainable thermosetting resin composition may not be sufficiently lowered and the adhesion force may be lowered. If the amount of the compound represented by Formula (1) is more than 90% by weight, phase separation may occur between the compound represented by Formula (1) and other components. Thus, in the case of producing a film or the like using the obtainable thermosetting resin composition, the coating property may be lowered or the water absorbability of an adhesive layer may be increased. The lower limit of the amount of the compound represented by Formula (1) in the epoxy resin is more preferably 5% by weight and the upper limit thereof is more preferably 80% by weight.

The thermosetting resin composition of the present invention preferably further contains a polymer compound. The polymer compound provides an obtainable thermosetting resin composition with a film forming property or flexibility. As a result, a thermosetting resin composition excellent in bonding reliability is obtained.

The polymer compound is not particularly limited, and is preferably a polymer compound having a functional group reactive with an epoxy resin.

The polymer compound having a functional group reactive with an epoxy resin is not particularly limited, and examples thereof include polymer compounds having, for example, an amino group, a urethane group, an imide group, a hydroxyl group, a carboxyl group, or an epoxy group. Among these, a polymer compound having an epoxy group is preferable.

In the case where the thermosetting resin composition of the present invention contains the epoxy resin having a polycyclic hydrocarbon skeleton in the main chain and the polymer compound having an epoxy group, a cured product of the thermosetting resin composition is excellent in mechanical strength, heat resistance, and damp proofness, which are derived from the epoxy resin having a polycyclic hydrocarbon skeleton in the main chain, and is excellent in flexibility, which is derived from the polymer compound having an epoxy group. Further, the cured product is excellent in thermal shock cycle resistance, solder reflow resistance, dimension stability and the like, realizing high bonding reliability and high conduction reliability.

The polymer compound having an epoxy group is not particularly limited as long as it is a polymer compound having an epoxy group at a terminal and/or in a side chain (pendant position). Examples thereof include an epoxy group-containing acrylic rubber, an epoxy group-containing butadiene rubber, a bisphenol-type high molecular weight epoxy resin, an epoxy group-containing phenoxy resin, an epoxy group-containing acrylic resin, an epoxy group-containing urethane resin, and an epoxy group-containing polyester resin. Each of these polymer compounds having an epoxy group may be used alone, or two or more of these may be used in combination. Among these, an epoxy group-containing acrylic resin is preferable because it contains a lot of, epoxy groups to further enhance the mechanical strength and heat resistance of a cured product of an obtainable thermosetting resin composition.

The polymer compound may have a photocurable functional group, in addition to the functional group reactive with an epoxy resin.

The polymer compound having the photocurable functional group provides an obtainable thermosetting resin composition with photocurability. Such a thermosetting resin composition can be semi-cured by photoirradiation. The adhesion force or bonding force of an adhesive layer, or the like formed of the thermosetting resin composition can be controlled by photoirradiation.

The photocurable functional group is not particularly limited, and examples thereof include an acrylic group and a methacrylic group.

The weight average molecular weight of the polymer compound is not particularly limited. The preferable lower limit thereof is 10 thousand and the preferable upper limit thereof is one million. If the weight average molecular weight of the polymer compound is less than 10 thousand, an obtainable thermosetting resin composition may give a cured product having insufficient adhesion force or may be hardly filmed on the occasion of filming thereof. Further, the film forming property of the thermosetting resin composition may be insufficient to fail to sufficiently enhance the flexibility of the cured product. If the weight average molecular weight of the polymer compound is more than one million, an obtainable thermosetting resin composition may have lowered surface wettability in the bonding process, resulting in lowered adhesion strength.

In the case where the thermosetting resin composition of the present invention contains the polymer compound, the amount of the polymer compound is not particularly limited. The preferable lower limit is 20 parts by weight and the preferable upper limit is 100 parts by weight, per 100 parts by weight of the epoxy resin. If the amount of the polymer compound is less than 20 parts by weight, a cured product of an obtainable thermosetting resin composition may have lowered flexibility, failing to achieve high bonding reliability and high conduction reliability. If the amount of the polymer compound is more than 100 parts by weight, a cured product of an obtainable thermosetting resin composition may have low mechanical strength, low heat resistance, and low damp proofness, failing to achieve high bonding reliability and high conduction reliability.

The thermosetting resin composition of the present invention contains an acid anhydride having a bicyclo skeleton.

Since the thermosetting resin composition of the present invention contains an acid anhydride having a bicyclo skeleton that is sterically bulky, the reactivity of the curing reaction is suppressed. For this reason, the thermosetting resin composition of the present invention can express excellent storage stability and thermal stability even if it contains an imidazole curing accelerator that is in a liquid form at an ordinary temperature.

Moreover, the acid anhydride having a bicyclo skeleton is highly soluble in the epoxy resin and solvent, and is uniformly dissolved. Thus, the thermosetting resin composition of the present invention achieves high transparency. For example, automatic recognition of a pattern or position indication with a camera is easy on the occasion of semiconductor chip bonding. Moreover, since the thermosetting resin composition of the present invention contains the acid anhydride having a bicyclo skeleton, the cured product of the composition exerts excellent mechanical strength, heat resistance, electric property, or the like.

The acid anhydride having a bicyclo skeleton is not particularly limited, and is preferably a compound having a structure represented by Formula (a).

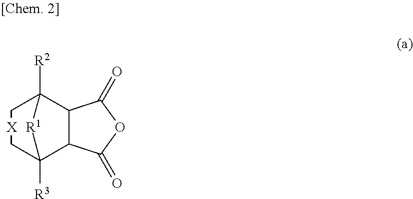

In Formula (a), X represents a linking group of a single or double bond, R¹ represents a methylene or ethylene group, R² and R³ each represent a hydrogen atom, a halogen group, an alkoxy group, or a hydrocarbon group.

Specific examples of the compound represented by Formula (a) include nadic anhydride and methyl nadic anhydride. Each of these may be used alone, or two or more of these may be used in combination.

Commercial products of the acid anhydride having a bicyclo skeleton is not particularly limited, and examples thereof include YH-307 and YH-309 (both produced by Japan Epoxy resin Co Ltd.) and RIKACID HNA-100 (produced by New Japan Chemical Co., Ltd.). Each of these may be used alone, or two or more of these may be used in combination.

The amount of the acid anhydride having a bicyclo skeleton is not particularly limited, and the preferable lower limit thereof is 60%, and the preferable upper limit is 110%, of the theoretically required equivalent to the total amount of the epoxy groups in the thermosetting resin composition of the present invention. If the amount of the acid anhydride having a bicyclo skeleton is less than 60% of the theoretically required equivalent, an obtainable thermosetting resin composition may not be sufficiently cured, or the mechanical strength, heat resistance, electric property, or the like of the cured product thereof may be deteriorated. The amount of the acid anhydride having a bicyclo skeleton exceeding 110% of the theoretically required equivalent does not especially contribute to enhancement of the curability. The more preferable lower limit of the amount of the acid anhydride having a bicyclo skeleton is 70%, and the more preferable upper limit is 100%, of the theoretically required equivalent to the total amount of the epoxy groups in the thermosetting resin composition of the present invention.

The thermosetting resin composition of the present invention contains an imidazole curing accelerator that is in a liquid form at an ordinary temperature.

The term “a liquid form at an ordinary temperature” herein refers to a liquid form at least at a temperature in a range of 10° C. to 30° C.

Commonly, addition of an imidazole curing accelerator enables thermosetting of an obtainable thermosetting resin composition at comparatively low temperatures in a short time. However, most imidazole curing accelerators are in a solid form at an ordinary temperature and are finely powdered to be blended, which causes a reduction in the transparency. In contrast, use of an imidazole curing accelerator that is in a liquid form at an ordinary temperature allows the thermosetting resin composition of the present invention to have high transparency, and thereby facilitating automatic recognition of a pattern or position indication with a camera on the occasion of semiconductor chip bonding, for example.

Moreover, since the imidazole curing accelerator that is in a liquid form at an ordinary temperature can be uniformly dispersed at the molecular level, the thermosetting resin composition of the present invention avoids local heat generation on the occasion of semiconductor chip bonding, thereby preventing formation of voids.

Moreover, the imidazole curing accelerator that is in a liquid form at an ordinary temperature is used in combination with an acid anhydride having a sterically bulky bicyclo skeleton as mentioned above. Therefore, the thermosetting resin composition of the present invention exerts excellent storage stability and thermal stability even when it contains the imidazole outing accelerator that is in a liquid form at an ordinary temperature.

Furthermore, use of the imidazole compound that is in a liquid form at an ordinary temperature does not need a process of finely pulverizing the imidazole curing accelerator, and also clogging of filters during filtration is suppressed. Therefore, the thermosetting resin composition of the present invention is easily produced.

The imidazole curing accelerator that is in a liquid form at an ordinary temperature is not particularly limited as long as it is in a liquid form at an ordinary temperature, and may be a single compound or a composition. In the case that the imidazole curing accelerator that is in a liquid form at an ordinary temperature is a composition, the composition may be one obtained by mixing an imidazole compound that is in a liquid form at an ordinary temperature and at least one another compound, or may be one obtained by mixing an imidazole compound that is in a solid form at an ordinary temperature and at least one another compound so as to be made into a liquid form.

In the case that the imidazole curing accelerator that is in a liquid form at an ordinary temperature is a single compound, examples of the imidazole curing accelerator that is in a liquid form at an ordinary temperature include imidazole compounds such as 2-ethyl-4-methylimidazole, 1-methylimidazole, 1-cyanoethyl-2-ethyl-4-methylimidazole, 1-benzyl-2-methylimidazole, 1-cyanoethyl-2-methylimidazole, 1-benzyl-2-ethylimidazole, 1-benzyl-2-phenylimidazole, 1-cyanoethyl-2-phenyl-4,5-di-(cyanoethoxymethyl)imidazole, 1,8-diazabicyclo(5.4.0)undecene-7, and derivatives of these.

The derivatives are not particularly limited, and examples thereof include salts such as carboxylate, isocyanurate, phosphate, phosphite, and phosphonate, and adducts with an epoxy compound.

Each of these may be used alone, or two or more of these may be used in combination.

In the case that the imidazole curing accelerator that is in a liquid form at an ordinary temperature is a composition, the imidazole curing accelerator that is in a liquid form at an ordinary temperature preferably contains an imidazole compound that is in a liquid fort or in a solid form at an ordinary temperature and a phosphorous compound.

In this case, an imidazole group in the imidazole compound that is in a liquid form or in a solid form at an ordinary temperature is stabilized by a hydroxyl group in the phosphorous compound. Thus, the imidazole curing accelerator that is in a liquid form at an ordinary temperature has excellent stability and curability. As a result, an obtainable thermosetting resin composition has superior storage stability and thermal stability, and can more sufficiently avoid local heat generation on the occasion of semiconductor chip bonding, thereby preventing formation of voids.

Examples of the imidazole compound that is in a liquid form or solid form at an ordinary temperature include imidazole, 2-methylimidazole, 2-undecylimidazole, 2-heptadecylimidazole, 1,2-dimethylimidazole, 2-ethyl-4-methylimidazole, 2-phenylimidazole, 2-phenyl-4-methylimidazole, 1-benzyl-2-methylimidazole, 1-benzyl-2-phenylimidazole, 1-cyanoethyl-2-methylimidazole, 1-cyanoethyl-2-undecylimidazole, 1-cyanoethyl-2-ethyl-4-methylimidazole, 1-cyanoethyl-2-phenylimidazole, and 1-aminomethyl-2-methylimidazol. Each of these may be used alone, or two or more of these may be used in combination.

Examples of the phosphorous compound include phosphorous acid, phosphorous acid monoester, and phosphorous acid diester.

Examples of the phosphorous acid monoester include monomethyl phosphite, monoethyl phosphite, monobutyl phosphite, monolauryl phosphite, monooleyl phosphite, monophenyl phosphite, and mononaphthyl phosphite. Examples of the phosphorous acid diester include dimethyl phosphite, diethyl phosphite, dibutyl phosphite, dilauryl phosphite, dioleyl phosphite, diphenyl phosphite, dinaphthyl phosphite, di-o-tolyl phosphite, di-m-tolyl phosphite, di-p-tolyl phosphite, di-p-chlorophenyl phosphite, di-p-bromophenyl phosphite, and di-p-fluorophenyl phosphite.

Each of these may be used alone, or two or more of these may be used in combination.

The blending ratio of the imidazole compound that is in a liquid form or solid form at an ordinary temperature and the phosphorous compound is not particularly limited. The molar ratio of the hydroxyl group in the phosphorous compound to the imidazole group in the imidazole compound that is in a liquid form or solid form at an ordinary temperature is preferably 0.05 in the lower limit and 3.3 in the upper limit. The molar ratio of less than 0.05 leads to difficulty in stabilization of the imidazole group by the hydroxyl group in, the phosphorous compound. As result, the thermosetting resin composition may have deteriorated storage stability or thermal stability. The molar ratio of more than 3.3 may lower the curability of the imidazole curing accelerator that is in a liquid form at an ordinary temperature. The molar ratio of the hydroxyl group in the phosphorous compound to the imidazole group in the imidazole compound that is in a liquid form or solid form at an ordinary temperature is more preferably 0.07 in the lower limit and more preferably 3.2 in the upper limit.

Commercial products of the imidazole curing accelerator that is in a liquid form at an ordinary temperature are not particularly limited, and examples thereof include 2E4MZ, 1B2MZ, 1B2PZ, 2MZ-CN, 2E4MZ-CN, 2PHZ-CN, 1M2EZ, 1B2EZ (all produced by SHIKOKU CHEMICALS CORPORATION), EMI24 (produced by Japan Epoxy Resin Ltd.), and Fujicure 7000 (produced by FUJI KASEI CO. LTD.). Among the examples, Fujicure 7000 (produced by FUJI KASEI. CO., LTD.) is preferable. Each of these may be used alone, or two or more of these may be used in combination.

The amount of the imidazole curing accelerator that is in a liquid form at an ordinary temperature is not particularly limited. The lower limit thereof is preferably 5 parts by weight and the upper limit thereof is preferably 50 parts by weight, for each 100 parts by weight of the acid anhydride having a bicyclo skeleton. If the amount of the imidazole curing accelerator that is in a liquid form at an ordinary temperature is less than 5 parts by weight, an obtainable thermosetting resin composition may require heating at high temperatures for a long time period for thermosetting. If the amount of the imidazole curing accelerator that is in a liquid form at an ordinary temperature is more than 50 parts by weight, an obtainable thermosetting resin composition may have deteriorated storage stability and thermal stability.

The lower limit of the amount of the imidazole curing accelerator that is in a liquid format an ordinary temperature is more preferably 10 parts by weight and the upper limit thereof is more preferably 30 parts by weight, for each 100 parts by weight of the acid anhydride having a bicyclo skeleton.

The thermosetting resin composition of the present invention may contain an inorganic filler, if necessary.

Addition of an inorganic filler can enhance the mechanical strength and heat resistance of the cured product, and also can reduce the linear expansion coefficient of an obtainable thermosetting resin composition, thereby achieving high bonding reliability.

The inorganic filler is not particularly limited, and examples thereof include silica, alumina, aluminum nitride, boron nitride, silicon nitride, silicon carbonate, magnesium oxide, and zinc oxide.

The inorganic filler preferably has a refractive index difference of not more than 0.1 with the epoxy resin in terms of maintaining high transparency of an obtainable thermosetting resin composition.

Examples of the inorganic filler include oxides of titanium, aluminum, calcium, boron, magnesium and zirconium, and complexes thereof, and more specific examples thereof include a silicon-aluminum-boron complex oxide, silicon-titanium complex oxide, and silica-titania complex oxide.

In the case that the refractive index difference between the inorganic filler and the epoxy resin exceeds 0.1, the inorganic filler preferably has an average particle diameter of less than 0.3 μm in terms of maintaining high transparency of an obtainable thermosetting resin composition.

Moreover, in terms of achieving both of the high bonding reliability and the high transparency, plural kinds of inorganic fillers having different particle diameters May be used in combination within the range not deteriorating the effects of the present invention. The inorganic filler is particularly preferably a spherical silica having a hydrophobic-treated surface.

The upper limit of the average particle diameter of the inorganic filler is not particularly limited, and the upper limit thereof is preferably 10 μm. The average particle diameter of the inorganic filler exceeding 10 μm deteriorates the transparency of an obtainable thermosetting resin composition. As a result, automatic recognition of a pattern or position indication with a camera may become difficult on the occasion of semiconductor chip bonding. The average particle diameter of the inorganic filler exceeding 10 μm may cause bonding failure of the electrode due to the large average particle diameter of the inorganic filler.

The upper limit of the average particle diameter of the inorganic filler is more preferably 5 μm.

In the case that the thermosetting resin composition of the present invention contains the inorganic filler, the amount of the inorganic filler is not particularly limited. The upper limit of the amount of the inorganic filler in the thermosetting resin composition of the present invention is preferably 70% by weight. If the amount of the inorganic filler exceeds 70% by weigh, a cured product of an obtainable thermosetting resin composition has a higher elastic-modulus, and thus cannot reduce the thermal stress. As a result, a high bonding reliability may not be achieved. The upper limit of the amount of the inorganic filler in the thermosetting resin composition of the present invention is more preferably 60% by weight.

The thermosetting resin composition of the present invention may further contain common resins such as an acrylic resin, a polyimide, a polyamide, and a phenoxy; resin, and may further contain additives such as a silane coupling agent, a titanate coupling agent, a viscosifier, and an antifoaming agent, if needed. Moreover, in the case of allowing the thermosetting resin composition of the present invention to have photocurability, it may further contain, for example, a polyfunctional(meth)acrylate compound, a photo initiator, or the like.

A method for producing the thermosetting resin composition of the present invention is not particularly limited. An exemplary method includes stirring and mixing the epoxy resin, the acid anhydride having a bicyclo skeleton, the imidazole curing accelerator that is in a liquid form at an ordinary temperature, and materials added according to need with a homodisper or the like. In the case that the imidazole curing accelerator that is in a liquid form at an ordinary temperature contains an imidazole compound that is in a liquid format an ordinary temperature and a phosphorous compound, a composition obtained by preliminary mixing these materials may be added, or these materials may be added separately.

A cured product of the thermosetting resin composition of the present invention preferably has as high a glass transition temperature as possible in terms of the heat resistance and mechanical strength of the cured product, and also in terms of the bonding reliability, or the like in the case where the thermosetting resin composition is used for a flip-chip mounting adhesive. A higher glass transition temperature maintains a glass state of the cured product in a wider temperature range, and achieves a high elastic modulus, a low linear expansion coefficient, and a low water absorption coefficient. Thus, the thermosetting resin composition exerts a high bonding reliability when it is used for a flip-chip mounting adhesive.

The glass transition temperature of the thermosetting resin composition of the present invention is not particularly limited, and is preferably not lower than 175° C. to provide a mounting body having sufficiently high bonding reliability.

Application of the thermosetting resin composition of the present invention is not particularly limited. The thermosetting resin composition is, preferably applied for adhesives for bonding a semiconductor used for bonding a semiconductor chip to a substrate or another semiconductor chip. Among such adhesives, the thermosetting resin composition of the present invention is more preferably used for a flip-chip mounting adhesive to mount a flip-chip which has a plurality of bumps serving as electrodes on the surface, an under fill material, or the like. In particular, the thermosetting resin composition of the present invention is preferably used for a precoating-type flip-chip mounting adhesive which is preliminary applied to a wafer or a semiconductor chip.

In the precoating-type flip-chip mounting, patterns or position indications on the surface of a wafer or a semiconductor chip and protruding electrodes are covered by an adhesive layer, and thus they are not directly observed. For this reason, the adhesive needs to have high transparency. Moreover, in the precoating-type flip-chip mounting, bonding of the wafer or the semiconductor chip to a counter substrate is performed while the adhesive layer is preliminary interposed therebetween. Thus, once a void is formed, it is more difficult to remove the void than the case of a post-insertion type under fill material that is provided after the bonding. Furthermore, in the precoating-type flip-chip mounting, it takes a long time from supply of the adhesive to bonding. Therefore, the adhesive needs to have a long time stability at an ordinary temperature or high temperature.

The thermosetting resin composition of the present invention has advantages that it has excellent storage stability and thermal stability while maintaining high transparency and suppressing formation of voids on the occasion of semiconductor chip bonding. Therefore, the thermosetting resin composition of the present invention exerts its advantages especially in the case of its use for flip-chip mounting adhesives.

The adhesive for semiconductor bonding or the flip-chip mounting adhesive mentioned earlier may be in a paste form (non-conductive paste, NCP) or in a sheet form or film form (non-conductive film, NCF).

The thermosetting resin composition of the present invention is also preferably used for a non-conductive film functioning as a back grinding tape (BG-NCF), or the like.

Meanwhile, the non-conductive film functioning as a back grinding tape (BG-NCF) herein refers to a film including at least a substrate film and an adhesive layer. The film is attached as a back grinding tape to the face of a wafer where a plurality of protrusions (bumps) are formed as electrodes. Then, only the substrate film is removed and the adhesive layer left on the wafer is used on the occasion of bonding to a substrate or another semiconductor chip.

In the case of using the thermosetting resin composition of the present invention for a BG-NCF, dice cutting is carried out on a wafer to which an adhesive layer formed of the thermosetting resin composition of the present invention is attached. On that occasion, recognition of a cutting plane line indicating a dice-cutting site on the wafer surface is conducted by a camera through the adhesive layer, in the same manner as recognition of a pattern or position indication. Accordingly, because of the high transparency of the adhesive layer formed of the thermosetting resin composition of the present invention, automatic recognition of the cutting plane line with a camera on the occasion of dice cutting of a wafer is also facilitated, leading to improvement in productivity of a semiconductor device.

The thermosetting resin composition of the present invention preferably has a haze value of not more than 70%. If the haze value is more than 70%, the transparency of the thermosetting resin composition is lowered, resulting in difficulty in automatic recognition of a pattern or position indication with a camera on the occasion of semiconductor chip bonding. Moreover, automatic recognition of the cutting plane line with a camera becomes difficult upon dicing of a wafer, and thus productivity of a semiconductor device may be deteriorated. The thermosetting resin composition of the present invention more preferably has a haze value of not more than 65%.

Meanwhile, the haze value herein refers to a haze value (%) of an adhesive film measured with a haze meter such as “HM-150” produced by MURAKAMI COLOR RESEARCH LABORATORY CO., Ltd. Here, the adhesive film is prepared by sandwiching an adhesive layer (40 μm in thickness) formed of the thermosetting resin composition between two sheets of PET films (25 μm in thickness).

A flip-chip mounting adhesive containing the thermosetting resin composition of the present invention is also one aspect of the present invention. The flip-chip mounting adhesive of the present invention may be in a paste form, or may be in a sheet form or a film form.

The flip-chip mounting adhesive of the present invention has excellent storage stability and thermal stability while maintaining high transparency and suppressing formation of voids on the occasion of semiconductor chip bonding. Thus, the flip-chip mounting adhesive is preferably used in a method for producing a semiconductor device. In the method, an adhesive layer is formed on a surface with protruding electrodes of a wafer having protruding electrodes on the surface, followed by dividing the resulting wafer into individual semiconductor chips.

A method for producing a semiconductor device using the flip-chip mounting adhesive of the present invention, which includes the steps of: supplying the flip-chip mounting adhesive of the present invention to a wafer on a surface having a protruding electrode to farm an adhesive layer; dicing the wafer together with the adhesive layer to provide separated semiconductor chips having the adhesive layer; and mounting the semiconductor chips having the adhesive layer on a substrate or another semiconductor chip through the adhesive layer by thermo-compression bonding is also one aspect of the present invention.

In the method for producing a semiconductor device of the present invention, first, the flip-chip mounting adhesive of the present invention is supplied to a surface with protruding electrodes of a wafer having protruding electrodes on the surface so as to form an adhesive layer.

In the above process, a flip-chip mounting adhesive in a paste form may be applied to the surface with protruding electrodes of the wafer, or a flip-chip mounting adhesive in a sheet or film form may be attached to the surface by heat lamination, or the like.

The method for applying the flip-chip mounting adhesive in a paste form is not particularly limited. Examples of the method include a method in which the flip-chip mounting adhesive in a paste form is dissolved in a middle boiling solvent or a high boiling solvent having a boiling, point of around 120° C. to 250° C., such, as propyleneglycol methylether acetate, as a solvent to prepare an adhesive solution, and then the adhesive solution is directly printed on the surface with protruding electrodes of the wafer by a spin coater, screen printing, or the like, followed by drying the solvent.

Examples of the method for applying the flip-chip mounting adhesive in a paste form also include a method in which the flip-chip mounting adhesive in a paste form free from a solvent is applied on the surface with protruding electrodes of the wafer, and then the adhesive is made into a film with a B-staging agent or by exposure to light.

According to the method for producing a semiconductor device of the present invention, the aforementioned steps may be followed by a step of thinning the wafer by grinding it from the back surface.

If grinding is performed after forming the adhesive layer, the wafer is supported by the adhesive layer so that the wafer is less likely to be broken by the thinning, or the protruding electrode can be protected by the adhesive layer.

According to the method for producing a semiconductor device of the present invention, the aforementioned steps are followed by a step of dicing the wafer together with the adhesive layer into separated semiconductor chips having the adhesive layer.

In this step, recognition of a cutting plane line indicating a dice-cutting site on the wafer surface is conducted by a camera through the adhesive layer, in the same manner as recognition of a pattern or position. The flip-chip mounting adhesive of the present invention exerts its high transparency in the step, and thus automatic recognition of the cutting plane line by a camera is easily conducted.

According to the method for producing a semiconductor device of the present invention, a step of mounting semiconductor chips having the adhesive layer on a substrate or another semiconductor chip through the adhesive layer by thermo-compression bonding is further performed.

In this step, due to the high transparency of the flip-chip mounting adhesive of the present invention, automatic recognition of the pattern or position by a camera is easily performed.

Meanwhile, in this step, since the adhesive layer is preliminary integrated with the semiconductor chips on their surfaces, once voids are formed, the voids are not easily removed. However, use of the flip-chip mounting adhesive of the present invention can prevent local heat generation, thereby preventing formation of voids.

In the method for producing a semiconductor device of the present invention, it takes a long time from the supply of the adhesive to the bonding, and furthermore the adhesive layer is exposed to various heat histories such as heat generation during dicing. Therefore, the method for producing a semiconductor device of the present invention needs to use an adhesive having excellent long-term stability at an ordinary temperature or high temperature. Here, use of the flip-chip mounting adhesive of the present invention having excellent storage stability and thermal stability enables successful production of a semiconductor device.

A semiconductor device produced by the method for producing a semiconductor device of the present invention is also one aspect of the present invention.

### Advantageous Effects of Invention

The present invention provides a thermosetting resin composition which is easily produced, has excellent storage stability and thermal stability while maintaining high transparency and preventing formation of voids on the occasion of semiconductor chip bonding, and gives a cured product having excellent heat resistance. Furthermore, the present invention provides a flip-chip mounting adhesive containing the thermosetting resin composition, a method for producing a semiconductor device using the flip-chip mounting adhesive, and a semiconductor device produced by the method for producing a semiconductor device.

### DESCRIPTION OF EMBODIMENTS

The following description will discuss the embodiments of the present invention in more detail by showing examples. The present invention is not limited to those examples.

### Examples 1 to 11, Comparative Examples 1 to 10

### (1) Production of Adhesive Film

Based on the formulation in Table 1 or Table 2, the materials mentioned below were added to methylethylketone so that the solid concentration was adjusted to 50% by weight, and stirred and mixed using a homodisper. In this manner, a formulation solution of a thermosetting resin composition was prepared.

### (Epoxy Resin)

HP-7200HH (dicyclopentadiene-type epoxy resin, produced by DIC Corporation)

HP-7200 (dicyclopentadiene-type epoxy resin, produced by DIC Corporation).

EXA-4710 (naphthalene-type epoxy resin, produced by DIC Corporation)

EXA-4816 (aliphatic chain modified epoxy resin, produced by DIC Corporation)

EXA-850CRP (bisphenol A-type epoxy resin, produced by DIC Corporation)

### (Epoxy Group-Containing Acrylic Resin)

SK-2-78 (2-methacryloyloxyethyl isocyanate adduct of a copolymer of 2-ethylhexyl acrylate, isobornyl acrylate, hydroxyethyl acrylate, and glycidyl methacrylate, molecular weight: 520000, double bond equivalent: 0.9 meq/g, epoxy equivalent: 1650, produced by Shin-Nakamura Chemical Co., Ltd.)

G-2050M (glycidyl group-containing acrylic resin, weight average molecular weight: 200000, epoxy equivalent: 340, produced by NOF Corporation)

G-017581 (glycidyl group-containing acrylic resin, weight average molecular weight: 10000, epoxy equivalent: 240, produced by NOF Corporation)

### (Acid Anhydride)

YH-306 (acid anhydride without a bicyclo skeleton, produced by Mitsubishi Chemical Corporation)

RIKACID DDSA (acid anhydride without a bicyclo skeleton, produced by New Japan Chemical Co., Ltd.)

BTDA (acid anhydride without a bicyclo skeleton, produced by Daicel Corporation)

YH-309 (acid anhydride with a bicyclo skeleton, produced by Mitsubishi Chemical Corporation)

RIKACID HNA-100 (acid anhydride with a bicyclo skeleton, produced by New Japan Chemical Co., Ltd.)

### (Imidazole Curing Accelerator)

2MA-OK (solid at an ordinary temperature, produced by Shikoku Chemicals Corp.)

2P4MZ (solid at an ordinary temperature, produced by Shikoku Chemicals Corp.)

2MZ-CN (solid at an ordinary temperature, produced by Shikoku Chemicals Corp.)

C11Z-CN (solid at an ordinary temperature, produced by Shikoku Chemicals Corp.)

2PZ-CN (solid at an ordinary temperature, produced by Shikoku Chemicals Corp.)

FUJICURE 7000 (liquid at an ordinary temperature, produced by Fuji Kasei Co., Ltd.)

2E4MZ-CN (liquid at an ordinary temperature, produced by Shikoku Chemicals Corp.)

Imidazole curing accelerator A (liquid at an ordinary temperature, composition containing 2-ethyl-4-methylimidazol and dilauryl phosphite at a molar ratio of 1:1)

Imidazole curing accelerator B (liquid at an ordinary temperature, composition containing 2E4MZ-CN and dilauryl phosphite at a molar ratio of 1:1)

### (Other Materials)

MT-10 (fumed silica, produced by Tokuyama Corporation)

SE-1050-SPT (phenyltrimethoxysilane surface-treated spherical silica, average particle diameter: 0.3 μm, produced by Admatechs)

SX009-MJF (phenyltrimethoxysilane surface-treated spherical silica, average particle diameter: 0.5 μm, produced by Admatechs)

AC4030 (stress relaxation rubber-type polymer, produced by Ganz Chemical. Co., Ltd.)

J-5800 (core shell-type stress relaxing agent, Mitsubishi Rayon Co., Ltd.).

The obtained formulation solution of the thermosetting resin composition was filtered by centrifugation through a 5-μm mesh, and then applied onto a release-treated PET film using an applicator (produced by Tester Sangyo Co., Ltd.), followed by drying at 100° C. for five minutes. Thereby, an adhesive film having a thickness of 40 μm was provided.

### (2) Mounting of Semiconductor Chip

A silicon wafer (diameter: 20 cm, thickness: 700 μm) which had a plurality of square copper bumps (height: 40 μm, width: 100 μm×100 μm) on the surface thereof at 400-μm intervals was prepared. An adhesive film was attached to the surface with the copper bumps of the silicon wafer at 70° C. under vacuum (1 torr) with a vacuum laminator.

Subsequently, the adhesive film-attached silicon wafer was placed in a polishing apparatus, and was polished from the back side until the thickness of the silicon wafer reached about 100 μm. At this time, the polishing was performed while water was sprayed to the silicon wafer in order to prevent the friction heat generated by the polishing from increasing the temperature of the silicon wafer. After the polishing, the silicon wafer was subjected to chemical mechanical polishing (CMP) for mirror finishing with an alkali silica-dispersed aqueous solution.

The polished, adhesive film-attached silicon wafer was removed from the polishing apparatus. A dicing tape “PE tape #6318-B” (produced by Sekisui Chemical Co., Ltd., thickness: 70 μm, base material: polyethylene, adhesive: 10 μm of rubber adhesive) was attached to the surface of the silicon wafer where the adhesive film was not attached, and the resulting product was mounted on a dicing frame. A PET film was peeled off from the adhesive layer of the adhesive film so that a polished silicon wafer having the adhesive layer was provided. The silicon wafer having the adhesive layer was diced together with the adhesive layer at a feed speed of 50 mm/sec using a dicing saw “DFD651” (produced by DISCO Corporation) into semiconductor chips with the adhesive layer each having a size of 10 mm×10 mm.

The semiconductor chips having the adhesive layer were thermo-compressed onto a substrate at a load of 0.15 MPa at 280° C. for 10 seconds using an automatic bonder (FC3000S, produced by Toray Engineering Co., Ltd.). Next, the adhesive layer was cured at 190° C. for 30 minutes, thereby providing semiconductor chip mounting bodies.

### (Evaluation)

The formulation solution of the thermosetting resin compositions, adhesive films, and semiconductor chip mounting bodies obtained in examples and comparative examples were evaluated on the following items. Table 1 and Table 2 show the results.

### (Productivity)

The obtained formulation solution of the thermosetting resin composition was filtered by centrifugation through a 5-μm mesh. A residue left on the mesh was dried, and the dried product was weighed.

The sample was evaluated as “o” if the ratio of the weight of the dried residue to the weight of the solid portion in the formulation solution before the centrifugal filtration was less than 5%, “Δ” if the ratio was not less than 5% and less than 10%, and “x” if the ratio was not less than 10%.

Meanwhile, the samples of examples or comparative examples whose productivity was evaluated as “x” in this evaluation were not evaluated for the item (2) and subsequent items.

### (2) Storage Stability

The storage stability was evaluated by measuring the initial gel fraction (% by weight) and the gel fraction (% by weight) after two-week storage at room temperature in the following procedure.

A 50 mm×100 mm plane rectangular test specimen was cut out from the adhesive film, and the specimen was weighed. The test specimen was put into ethyl acetate to be immersed at room temperature for 24 hours. Then, the test specimen was taken out of the ethyl acetate, and dried at 110° C. for one hour. The dried test specimen was weighed, and the gel fraction (% by weight) was calculated from the following equation (1).

Gel fraction (% by weight)=W2/W1×100 (1)

In equation (1), W1 represents the weight of the test specimen before the immersion, and W2 represents the weight of the test specimen after the immersion and drying.

The gel fraction was measured before and after two weeks storage at room temperature. The rate of increase in the gel fraction (% by weight) was calculated based on the following equation (2).

Rate of increase in gel fraction (% by weight)=(Gel fraction after two weeks storage at room temperature)−(Initial gel fraction) (2)

The test specimen was evaluated as “o” if the rate of increase in the gel fraction was less than 10% by weight, “Δ” if the rate of increase in the gel fraction was not lower than 10% by weight and less than 20% by weight, and “x” if the rate of increase in the gel fraction was not lower than 20% by weight.

### (3) Thermal Stability

A portion of the obtained adhesive film was sampled, and subjected to DSC measurement under the measurement conditions of 30° C. to 300° C. (5° C./min) and N₂=50 ml/min using a measurement device “DSC 6220” (produced by Seiko Instruments).

The initiation of the exothermic peak was observed. The adhesive film was evaluated as “o” if the exothermic starting temperature was not lower than 100° C., and “x” if the exothermic starting temperature was lower than 100° C.

### (4) Transparency

### (4-1) Haze Value

The 40-μm-thick adhesive film was sandwiched by two sheets of 25-μm-thick PET films so that a test specimen was obtained. The haze value (%) of the test specimen was measured with a haze meter (HM-150, produced by MURAKAMI COLOR RESEARCH LABORATORY CO., Ltd).

### (4-2) Automatic Recognition of Alignment Mark (Position Indication)

In the case where the number of the semiconductor chips whose alignment mark (position indication) was automatically recognizable was 10 out of 10 pieces of the semiconductor chips, the sample was evaluated as “o”, was evaluated as “Δ” if the number was 7 to 9, and was evaluated as “x” if the number was not more than 6, on the occasion of thermo-compressing the semiconductor chips having the adhesive layer on the substrate with an automatic bonder.

### (5) Heat Resistance

The adhesive film was cured in an oven at 190° C. for one hour so that a test sample was obtained. The dynamic viscoelasticity of the test sample was measured with a dynamic viscoelastic analyzer (DVA-200, produced by IT Keisoku Co., Ltd.) under the following conditions: tensile mode, distance between chucks: 30 mm, rate of temperature increase: 5° C./min, and measurement frequency: 10 Hz. The temperature at the peak of the tan θ was determined as a glass transition temperature (Tg). Generally, a higher Tg can be regarded as a higher heat resistance.

### (6) Voids

The semiconductor chip mounting body was observed with a scanning acoustic tomograph (SAT).

The semiconductor chip mounting body was evaluated as “o” if the ratio of the area where voids were formed to the area of the semiconductor chip was less than 5%, “Δ” if the ratio was not less than 5% and less than 10% by weight, and “x” if the ratio was not less than 10%.

TABLE 1

| | | | | Examples | | | | | | | | | | |
|---|---|---|---|---|---|---|---|---|---|---|---|---|---|---|
| | | | | 1 | 2 | 3 | 4 | 5 | 6 | 7 | 8 | 9 | 10 | 11 |
| Formulation | Epoxy resin | Dicyclopentadiene- | HP-7200HH | 94 | 94 | 94 | 94 | — | — | — | — | — | — | — |
| of adhesive | | type | HP-7200 | — | — | — | — | 94 | 94 | 94 | 94 | 94 | — | — |
| (parts by | | Naphthalene-type | EXA-4710 | 10 | 10 | 10 | 10 | 10 | 10 | 10 | 10 | 10 | — | — |
| weight) | | Aliphatic chain | EXA-4816 | — | — | — | — | — | — | — | — | — | 100 | — |
| | | modified | | | | | | | | | | | | |
| | | Bisphenol A-type | EXA-850CRP | — | — | — | — | — | — | — | — | — | — | 100 |
| | Epoxy group-containing acrylic resin | | SK-2-78 | 25 | 25 | 25 | 25 | — | — | — | — | — | — | — |
| | | | G-2050M | — | — | — | — | 20 | 20 | 20 | 20 | 20 | 20 | 20 |
| | | | G-017581 | — | — | — | — | 10 | 10 | 10 | 10 | 10 | 10 | 10 |
| | Acid | without bicyclo | YH-306 | — | — | — | — | — | — | — | — | — | — | — |
| | anhydride | skeleton | RIKACID | — | — | — | — | — | — | — | — | — | — | — |
| | | | DDSA | | | | | | | | | | | |
| | | | BTDA | — | — | — | — | — | — | — | — | — | — | — |
| | | with bicyclo | YH-309 | 44 | — | 44 | 44 | 49 | 49 | 49 | 49 | — | 37 | 71 |
| | | skeleton | RIKACID | — | 44 | — | — | — | — | — | — | 86 | — | — |
| | | | HNA-100 | | | | | | | | | | | |
| | Imidazole | Solid at an | 2MA-OK | — | — | — | — | — | — | — | — | — | — | — |
| | curing | ordinary | 2P4MZ | — | — | — | — | — | — | — | — | — | — | — |
| | accelerator | temperature | 2MZ-CN | | | | | | | | | | | |
| | | | C11Z-CN | — | — | — | — | — | — | — | — | — | — | — |
| | | | 2PZ-CN | — | — | — | — | — | — | — | — | — | — | — |
| | | Liquid at an | FUJICURE | 7 | 7 | — | — | 7 | — | — | — | — | — | — |
| | | ordinary | 7000 | | | | | | | | | | | |
| | | temperature | Imidazole | — | — | 7 | — | — | 7 | — | — | 7 | 7 | 7 |
| | | | curing | | | | | | | | | | | |
| | | | accelerator A | | | | | | | | | | | |
| | | | Imidazole | — | — | — | 7 | — | — | 7 | — | — | — | — |
| | | | curing | | | | | | | | | | | |
| | | | accelerator B | | | | | | | | | | | |
| | | | 2E4MZ-CN | — | — | — | — | — | — | — | 7 | — | — | — |

| | | | | | | | | | | | | |
|---|---|---|---|---|---|---|---|---|---|---|---|---|
| Other materials | MT-10 | 5 | 5 | 5 | 5 | — | — | — | — | — | — | — |
| | SE-1050-SPT | — | — | — | — | 90 | 90 | 90 | 90 | 90 | 90 | 90 |
| | SX009-MJF | — | — | — | — | 60 | 60 | 60 | 60 | 60 | 60 | 60 |
| | AC4030 | 5 | 5 | 5 | 5 | — | — | — | — | — | — | — |
| | J-5800 | — | — | — | — | 20 | 20 | 20 | 20 | 20 | 20 | 20 |

| | | | | | | | | | | | | | |
|---|---|---|---|---|---|---|---|---|---|---|---|---|---|
| Evaluation | Productivity | Evaluation | ◯ | ◯ | ◯ | ◯ | ◯ | ◯ | ◯ | ◯ | ◯ | ◯ | ◯ |
| | Storage | Rate of increase in gel fraction | 4 | 9 | 5 | 2 | 8 | 2 | 3 | 15 | 9 | 5 | 3 |
| | stability | after 2 weeks (wt %) | | | | | | | | | | | |
| | | Evaluation | ◯ | ◯ | ◯ | ◯ | ◯ | ◯ | ◯ | Δ | ◯ | ◯ | ◯ |
| | Thermal | Exothermic starting temperature | 121 | 110 | 120 | 115 | 129 | 120 | 115 | 127 | 105 | 118 | 119 |
| | stability | (° C.) | | | | | | | | | | | |
| | | Evaluation | ◯ | ◯ | ◯ | ◯ | ◯ | ◯ | ◯ | ◯ | ◯ | ◯ | ◯ |
| | Transparency | Haze value (%) | 29 | 33 | 30 | 28 | 63 | 64 | 61 | 62 | 63 | 65 | 60 |
| | | Automatic recognition of | ◯ | ◯ | ◯ | ◯ | ◯ | ◯ | ◯ | ◯ | ◯ | ◯ | ◯ |
| | | alignment mark | | | | | | | | | | | |
| | Heat | Glass transition temperature | 196 | 190 | 198 | 180 | 186 | 185 | 182 | 195 | 177 | 159 | 162 |
| | resistance | (° C.) | | | | | | | | | | | |
| | Voids | Evaluation | ◯ | ◯ | ◯ | ◯ | ◯ | ◯ | ◯ | Δ | ◯ | ◯ | ◯ |

TABLE 2

| | | | | Comparative Examples | | | | | | | | | |
|---|---|---|---|---|---|---|---|---|---|---|---|---|---|
| | | | | 1 | 2 | 3 | 4 | 5 | 6 | 7 | 8 | 9 | 10 |
| Formulation | Epoxy resin | Dicyclopentadiene- | HP-7200HH | 94 | 94 | — | — | — | — | — | — | — | — |
| of adhesive | | type | HP-7200 | — | — | 94 | 94 | 94 | 94 | 94 | 94 | 94 | 94 |
| (parts by | | Naphthalene-type | EXA-4710 | 10 | 10 | 10 | 10 | 10 | 10 | 10 | 10 | 10 | 10 |
| weight) | | Aliphatic chain | EXA-4816 | — | — | — | — | — | — | — | — | — | — |
| | | modified | | | | | | | | | | | |
| | | Bisphenol A-type | EXA-850CRP | — | — | — | — | — | — | — | — | — | — |
| | Epoxy group-containing acrylic resin | | SK-2-78 | 25 | 25 | — | — | — | — | — | — | — | — |
| | | | G-2050M | — | — | 20 | 20 | 20 | 20 | 20 | 20 | 20 | 20 |
| | | | G-017581 | — | — | 10 | 10 | 10 | 10 | 10 | 10 | 10 | 10 |
| | Acid | without bicyclo | YH-306 | 44 | — | — | — | — | — | — | 55 | — | — |
| | anhydride | skeleton | RIKACID | — | — | — | — | — | — | — | — | 128 | — |
| | | | DDSA | | | | | | | | | | |
| | | | BTDA | — | — | — | — | — | — | — | — | — | 75 |
| | | with bicyclo | YH-309 | — | 44 | 49 | 49 | 49 | 49 | 49 | — | — | — |
| | | skeleton | RIKACID | — | — | — | — | — | — | — | — | — | — |
| | | | HNA-100 | | | | | | | | | | |
| | Imidazole | Solid at an | 2MA-OK | — | 7 | 7 | — | — | — | — | — | — | — |
| | curing | ordinary | 2P4MZ | — | — | — | 7 | — | — | — | — | — | — |
| | accelerator | temperature | 2MZ-CN | — | — | — | — | 7 | — | — | — | — | — |
| | | | C11Z-CN | — | — | — | — | — | 7 | — | — | — | — |
| | | | 2PZ-CN | — | — | — | — | — | — | 7 | — | — | — |
| | | Liquid at an | FUJICURE | 7 | — | — | — | — | — | — | — | — | — |
| | | ordinary | 7000 | | | | | | | | | | |
| | | temperature | Imidazole | — | — | — | — | — | — | — | 7 | 7 | 7 |
| | | | curing | | | | | | | | | | |
| | | | accelerator A | | | | | | | | | | |
| | | | Imidazole | — | — | — | — | — | — | — | — | — | — |
| | | | curing | | | | | | | | | | |
| | | | accelerator B | | | | | | | | | | |
| | | | 2E4MZ-CN | — | — | — | — | — | — | — | — | — | — |

| | | | | | | | | | | | |
|---|---|---|---|---|---|---|---|---|---|---|---|
| Other materials | MT-10 | 5 | 5 | — | — | — | — | — | — | — | — |
| | SE-1050-SPT | — | — | 90 | 90 | 90 | 90 | 90 | 90 | 90 | 90 |
| | SX009-MJF | — | — | 60 | 60 | 60 | 60 | 60 | 60 | 60 | 60 |
| | AC4030 | 5 | 5 | — | — | — | — | — | — | — | — |
| | J-5800 | — | — | 20 | 20 | 20 | 20 | 20 | 20 | 20 | 20 |

| | | | | | | | | | | | | |
|---|---|---|---|---|---|---|---|---|---|---|---|---|
| Evaluation | Productivity | Evaluation | ◯ | Δ | Δ | X | Δ | Δ | Δ | ◯ | ◯ | X |
| | Storage | Rate of increase in gel fraction | 26 | 5 | 7 | — | 6 | 60 | 8 | 30 | 38 | — |
| | stability | after 2 weeks (wt %) | | | | | | | | | | |
| | | Evaluation | X | ◯ | ◯ | — | ◯ | X | ◯ | X | X | — |
| | Thermal | Exothermic starting temperature | 66 | 162 | 162 | — | 115 | 128 | 128 | 70 | 102 | — |
| | stability | (° C.) | | | | | | | | | | |
| | | Evaluation | X | ◯ | ◯ | — | ◯ | ◯ | ◯ | X | ◯ | — |
| | Transparency | Haze value (%) | 27 | 71 | 75 | — | 64 | 61 | 61 | 28 | 79 | — |
| | | Automatic recognition of | ◯ | Δ | X | — | ◯ | ◯ | ◯ | ◯ | X | — |
| | | alignment mark | | | | | | | | | | |
| | Heat | Glass transition temperature | 173 | 200 | 192 | — | 183 | 186 | 195 | 162 | 126 | — |
| | resistance | (° C.) | | | | | | | | | | |
| | Voids | Evaluation | ◯ | X | X | — | X | X | X | ◯ | X | — |

### INDUSTRIAL APPLICABILITY

The present invention provides a thermosetting resin composition which is easily produced, has excellent storage stability and thermal stability while maintaining high transparency and preventing formation of voids on the occasion of semiconductor chip bonding, and gives a cured product having excellent heat resistance. Furthermore, the present invention provides a flip-chip mounting adhesive containing the thermosetting resin composition, a method for producing a semiconductor device using the flip-chip mounting adhesive, and a semiconductor device produced by the method for producing a semiconductor device.

1. A thermosetting resin composition comprising
an epoxy resin,
an acid anhydride having a bicyclo skeleton, and
an imidazole curing accelerator that is in a liquid form at an ordinary temperature.

2. The thermosetting resin composition according to claim 1,
wherein the imidazole curing accelerator that is in a liquid form at an ordinary temperature includes an imidazole compound that is in a liquid form or solid form at an ordinary temperature, and
a phosphorous compound.

3. The thermosetting resin composition according to claim 1,
wherein the acid anhydride having a bicyclo skeleton is a compound represented by the formula (a): 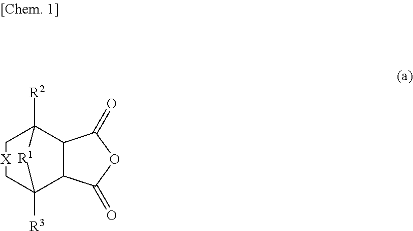
wherein X represents a linking group of a single or double bond, R¹ represents a methylene group or an ethylene group, R² and R³ each represent a hydrogen atom, a halogen group, an alkoxy group, or a hydrocarbon group.

4. The thermosetting resin composition according to claim 1,
wherein the epoxy resin includes an epoxy resin having a polycyclic hydrocarbon skeleton in a main chain.

5. A flip-chip mounting adhesive comprising the thermosetting resin composition according to claim 1.

6. A method for producing a semiconductor device using the flip-chip mounting adhesive according to claim 5, the method comprising the steps of:
supplying the flip-chip mounting adhesive to a wafer on a surface having a protruding electrode to form an adhesive layer;
dicing the wafer together with the adhesive layer to provide separated semiconductor chips having the adhesive layer; and
mounting the semiconductor chips having the adhesive layer on a substrate or another semiconductor chip through the adhesive layer by thermo-compression bonding.

7. The method for producing a semiconductor device according to claim 6, further comprising the step of
thinning the wafer by grinding it from a back surface thereof, after the step of supplying the flip-chip mounting adhesive to a wafer on a surface having a protruding electrode to form an adhesive layer.

8. A semiconductor device produced by the method for producing a semiconductor device according to claim 6.

9. The thermosetting resin composition according to claim 2,
the acid anhydride having a bicyclo skeleton is a compound represented by the formula (a): 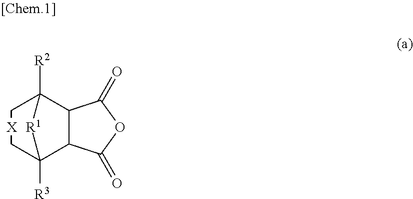
wherein X represents a linking group of a single or double bond, R¹ represents a methylene group or an ethylene group, R² and R³ each represent a hydrogen atom, a halogen group, an alkoxy group, or a hydrocarbon group.

10. The thermosetting resin composition according to claim 2,
wherein the epoxy resin includes an epoxy resin having a polycyclic hydrocarbon skeleton in a main chain.

11. The thermosetting resin composition according to claim 3,
wherein the epoxy resin includes an epoxy resin having a polycyclic hydrocarbon skeleton in a main chain.

12. The thermosetting resin composition according to claim 9,
wherein the epoxy resin includes an epoxy resin having a polycyclic hydrocarbon skeleton in a main chain.

13. A flip-chip mounting adhesive comprising the thermosetting resin composition according to claim 2.

14. A flip-chip mounting adhesive comprising the thermosetting resin composition according to claim 3.

15. A flip-chip mounting adhesive comprising the thermosetting resin composition according to claim 4.

16. A flip-chip mounting adhesive comprising the thermosetting resin composition according to claim 9.

17. A flip-chip mounting adhesive comprising the thermosetting resin composition according to claim 10.

18. A flip-chip mounting adhesive comprising the thermosetting resin composition according to claim 11.

19. A flip-chip mounting adhesive comprising the thermosetting resin composition according to claim 12.

20. A semiconductor device produced by the method for producing a semiconductor device according to claim 7.
